(19) United States
(12) Patent Application Publication
(10) Pub. No.: US 2026/0020155 A1
(43) Pub. Date: Jan. 15, 2026

(54) COIL ASSEMBLY AND COIL MODULE

(71) Applicant: Lanto Electronic Limited, Kunshan City (CN)

(72) Inventor: Bo KE, Kunshan City (CN)

(73) Assignee: Lanto Electronic Limited, Kunshan City (CN)

(21) Appl. No.: 19/266,839

(22) Filed: Jul. 11, 2025

(30) Foreign Application Priority Data
Jul. 12, 2024 (CN) 202410939175.2

(51) Int. Cl. H05K 1/16; H01F 27/06; H01F 27/28; H05K 1/11

(52) U.S. Cl. CPC H05K 1/165; H01F 27/2847; H05K 1/111; H01F 2027/065

(57) ABSTRACT

Provided is a coil assembly and a coil assembly and a coil module. The coil assembly includes a coil, a supporting member, and a circuit board. The supporting member includes a supporting ring and an extending board. The circuit board is arranged on an inner side of the supporting ring. The extending board includes a first end connected to the supporting ring and a second end extends towards the circuit board. The coil is arranged on the supporting ring and has a first end segment and a second end segment which are arranged on the extending board and extend to the circuit board. A first end of the coil is connected to a first pad of the circuit board, and a second end of the coil is connected to a second pad of the circuit board.

### CROSS-REFERENCE TO RELATED APPLICATION

This application claims the benefit of Chinese Patent Application No. 202410939175.2, filed on Jul. 12, 2024, entitled “Coil Assembly and Coil Module”, which is incorporated herein by reference in its entirety.

### FIELD OF THE DISCLOSURE

The present disclosure relates to wireless communication device technology, and more particularly to a coil assembly and a coil module.

### BACKGROUND

Near Field Communication (NFC) is a short-range communication technology, and is widely used in wireless charging, NFC tags, bus cards, access cards and other life fields. NFC performs data communication based on electromagnetic induction. In the NFC communication, a reader device passes an electric current through a coil, which in turn generates a magnetic field, and the magnetic field then induces an electric current within a tag. In a coil module in NFC, a coil is electrically connected to a circuit board. Based on cost consideration, the electromagnetic induction coil is very thin and is made of copper with high elasticity. The coil affects the performance of the NFC and needs improvement.

### SUMMARY

Embodiments of the present disclosure provide a coil assembly and a coil module.

One aspect of the present disclosure provides a coil assembly. The coil assembly includes: a coil, a supporting member, and a circuit board. The supporting member includes a supporting ring and an extending board. The circuit board is arranged on an inner side of the supporting ring, a first end of the extending board is connected to the supporting ring, a second end of the extending board extends towards the circuit board, the coil is arranged on the supporting ring, a first end segment and a second end segment of the coil are arranged on the extending board and extend to the circuit board, a first end of the coil is connected to a first pad of the circuit board, and a second end of the coil is connected to a second pad of the circuit board.

In some embodiments, the extending board and the circuit board are spaced apart from each other by a gap.

In some embodiments, the supporting member includes two guide grooves, the first end segment and the second end segment extend in the two guide grooves, respectively, and the first pad and the second pad are in an extending direction of the two guide grooves.

In some embodiments, each guide groove includes a first groove and a second groove communicated with the first groove, the first groove is arranged on an outer side of the supporting ring, the second groove is arranged on the extending board, and the second groove has an opening on a side close to the circuit board.

In some embodiments, the extending board is provided with a glue groove communicated with both the two guide grooves, the glue groove is filled with fixing glue, the fixing glue covers surfaces of the first end segment and the second end segment, the first end segment is fixed in the one of the two guide grooves by the fixing glue, and the second end segment is fixed in the other one of the two guide grooves by the fixing glue.

In some embodiments, the glue groove has a cross-type shape in a plan view.

In some embodiments, each of an outer side of the first end segment and an outer side of the second end segment is provided with a tin layer, and a length of the tin layer is greater than a maximum distance between the extending board and the circuit board.

In some embodiments, the coil assembly further includes a connection member, the connection member has a ring shape and is connected to a top end of the supporting ring, an outer diameter of the connection member is equal to an outer diameter of the supporting ring, an inner diameter of the connection member is less than an inner diameter of the supporting ring, and a top surface of the connection member and a top surface of the extending board are located in a same plane.

In some embodiments, the supporting ring and the coil are fixed and connected to each other by a glue layer.

Another aspect of the present disclosure provides a coil module, including: a coil assembly and a magnetic conductive sheet. The coil assembly includes: a coil; a supporting member including a supporting ring and an extending board; and a circuit board. The circuit board is arranged on an inner side of the supporting ring, a first end of the extending board is connected to the supporting ring, a second end of the extending board extends towards the circuit board, the coil is arranged on the supporting ring, a first end segment and a second end segment of the coil are arranged on the extending board and extend to the circuit board, a first end of the coil is connected to a first pad of the circuit board, a second end of the coil is connected to a second pad of the circuit board. The magnetic conductive sheet is disposed on a side of the supporting ring.

Embodiments of the present disclosure provide a coil assembly and a coil module. The coil assembly includes: a coil, a supporting member, and a circuit board. The supporting member includes a supporting ring and an extending board. The circuit board is arranged on an inner side of the supporting ring, a first end of the extending board is connected to the supporting ring, a second end of the extending board extends towards the circuit board, the coil is arranged on the supporting ring, a first end segment and a second end segment of the coil are arranged on the extending board and extend to the circuit board, a first end of the coil is connected to a first pad of the circuit board, and a second end of the coil is connected to a second pad of the circuit board. The extending board supports the first end segment and the second end segment between the supporting ring and the circuit board.

### BRIEF DESCRIPTION OF THE DRAWINGS

The various features and advantages of the disclosed examples will become apparent to those skilled in the art from the detailed description. The figures that accompany the detailed description can be briefly described as follows:

FIG. 1 is a perspective view of a coil assembly according to one or more embodiments of the present disclosure;

FIG. 2 is another perspective view of the coil assembly according to one or more embodiments of the present disclosure;

FIG. 3 is a perspective view of an extending board according to one or more embodiments of the present disclosure;

FIG. 4 is another perspective view of the extending board according to one or more embodiments of the present disclosure;

FIG. 5 is a perspective view of an extending board including a fixing glue according to one or more embodiments of the present disclosure; and

FIG. 6 is a perspective view showing connections of a magnetic conductive sheet, a coil, and a supporting ring of the coil assembly according to one or more embodiments of the present disclosure.

### REFERENCE NUMERAL LIST

10: coil; 11: first end segment; 12: second end segment;
20: supporting member; 21: supporting ring; 22: extending board;
23: guide groove; 231: first groove; 232: second groove;
24: glue groove; 25: fixing glue; 26: connection member;
27: glue layer; 28: tin layer; 30: circuit board; 31: pad;
40: magnetic conductive sheet; X: gap.

### DETAILED DESCRIPTION

The present disclosure is described below on the basis of the embodiments, but is not merely limited to these embodiments. Specific details are described in detail in the following detailed description of the present disclosure. The present disclosure can also be fully understood by a person skilled in the art without the description of the details. In order to avoid confusing the essence of the present disclosure, commonly known method, process, flow, element and circuit are not described in detail.

In addition, it should be understood by those skilled in the art, the drawings herein are provided for the purpose of illustration, and the drawings are not necessarily to scale.

Unless otherwise stated, the terms “comprise”, “include” and the like in the entire application document shall be interpreted as inclusive rather than exclusive or exhaustive; in other words, the terms mean “include but not limited to”.

In the descriptions of the present disclosure, it should be understood that the terms like “first”, “second” and the like are used for the purpose of description only, but cannot be considered to indicate or imply relative importance. In addition, in the descriptions of the present disclosure, unless otherwise stated, the meaning of “a plurality of” is two or more.

Unless otherwise stated or defined, the terms “install”, “connected”, “connect”, “fix” and the like should be understood in a broad sense, for example, the term “connected” may be fixedly connected or detachably connected or integrally connected, may be mechanically connected or electrically connected, may be directly connected or indirectly connected by means of an intermediate medium, and may be internally communicated or have an interaction relationship between two elements. A person skilled in the art can understand the specific meanings of the above terms in the present disclosure according to specific circumstances.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As described above, the electromagnetic induction coil is very thin and is made of copper with high elasticity. Therefore, an end portion of the coil may bend when a soldering is performed for connecting the coil and the circuit board, the end of the coil is difficult to align with a pad of the circuit board, or detachment between the end of the coil and the circuit board may occur after the soldering, causing low production efficiency and poor yield of the soldering.

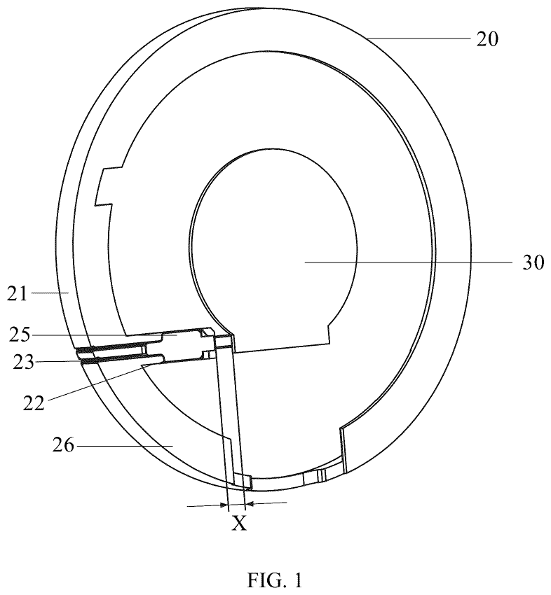

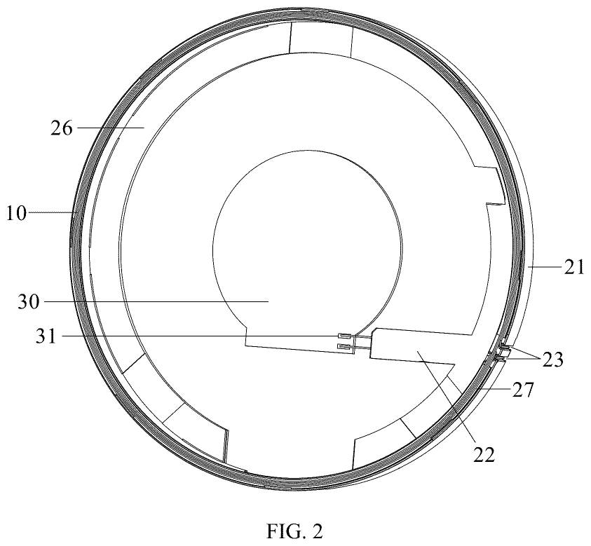

FIG. 1 and FIG. 2 are perspective views of a coil assembly from different view angles according to embodiments of the present disclosure. As shown in FIG. 2, the coil assembly includes a coil 10, a supporting member 20, and a circuit board 30. The supporting member 20 includes a supporting ring 21 and an extending board 22. The circuit board 30 is arranged on an inner side of the supporting ring 21. As shown in FIG. 1, the coil 10 is arranged on the supporting ring 21. As shown in FIG. 2, the coil 10 includes a first end segment 11 and a second end segment 12, and the first end segment 11 and the second end segment 12 are electrically connected to pads of the circuit board 30, respectively. For example, the first end segment 11 is an inlet end segment, and the second end segment 12 is an outlet end segment. As shown in FIG. 1, a first end of the extending board 22 is connected to the supporting ring 21, and a second end of the extending board (22) extends towards the circuit board 30. The first end segment 11 and the second end segment 12 of the coil 10 are partially arranged on the extending board 22 and further extend to the circuit board 30, a first end (end of the first end segment 11) of the coil 10 is connected to a first pad 31 of the circuit board 30, and a second end (end of the second end segment 12) of the coil 10 is connected to a second pad 31 of the circuit board 30. The extending board 22 supports the first end segment 11 and the second end segment 12 of the coil 10. Therefore, during the soldering process for connecting the coil 10 and the circuit board 30, the coil 10 is not easy to bend and offset, and the soldering stability between the coil 10 and the circuit board 30 is improved.

As shown in FIG. 2, other part (the part between the first end segment 11 and the second end segment 12) of the coil 10 is fixed on the supporting ring 21, for example, by a glue layer 27. The first end segment 11 and the second end segment 12 are fixed on the extending board 22, for example, by a glue layer. The extending board 22 and the circuit board 30 are spaced apart by a gap X. Accordingly, the mounting of the circuit board 30 is not interfered by the extending board 22. In some embodiments, the shape of the extending board 22 is determined according to the specific structure of the circuit board 30. The second end of the extending board 22 is closer to the circuit board 30 than the first end of the extending board 22. For example, the second end of the extending board 22 has a shape matching the circuit board 30 such that the extending board 22 matches the circuit board 30 without influencing the circuit board 30.

In some embodiments, a length of the extending board 22 is at least 60% of a distance between the supporting ring 21 and the circuit board 30. With such arrangement, the extending board 22 provides sufficient supporting for the first end segment 11 and the second end segment 12. In addition, the sufficient length of the extending board 22 makes the extending board 22 extend towards the pads 31 on the circuit board 30. It is noted that the specific length of the extending board 22 may be determined according to the specific structure.

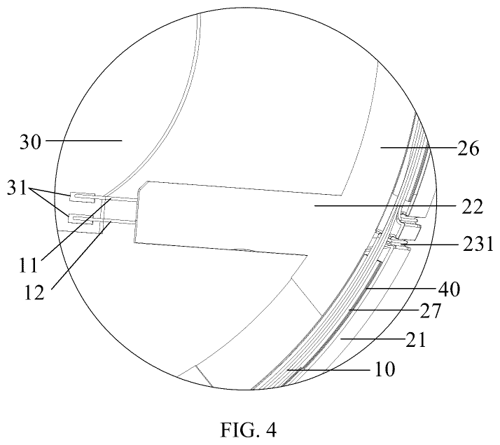

As shown in FIG. 1, the first end segment 11 and the second end segment 12 extend to the outer side of the supporting ring 21, and further extend and are electrically connected to the circuit board 30. The supporting member 20 is provided with two guide grooves 23, and the first end segment 11 and the second end segment 12 are arranged in the two guide grooves 23, respectively. In some embodiments, the two guide grooves 23 are parallel to each other, and thus the first end segment 11 and the second end segment 12 do not cross each other and are not twisted. The guide grooves 23 limit positions of the first end segment 11 and the second end segment 12, fix the first end segment 11 and the second end segment 12, and guide the extending directions of the first end segment 11 and the second end segment 12. As shown in FIG. 2 and FIG. 4, the pads 31 of the circuit board 30 are located in the extending direction of the guide grooves 23, respectively. Therefore, the first end segment 11 and the second end segment 12 extending along the guide grooves 23 are aligned with their corresponding pads 31 on the circuit board 30.

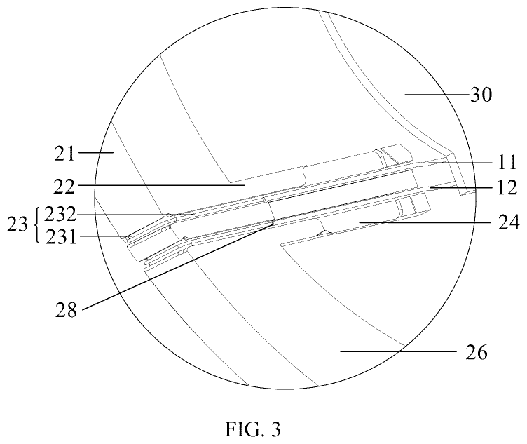

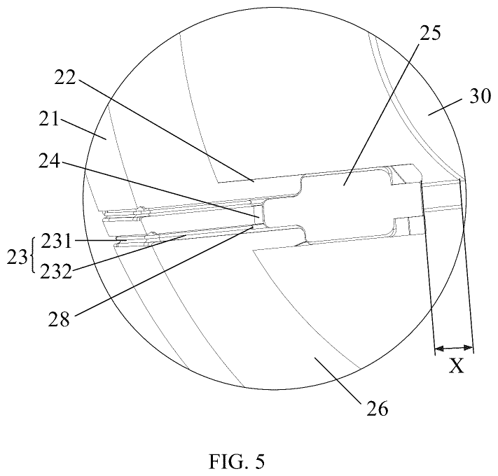

As shown in FIG. 3 and FIG. 5, the guide groove 23 includes a first groove 231 and a second groove 232 communicated with the first groove 231. The first groove 231 is formed on the outer side surface of the supporting ring 21, and the second groove 232 is formed on the extending board 22. For example, the first groove 231 is a concave formed on the outer side surface of the supporting ring 21, the second groove 232 is a concave formed on the rear surface of the extending board 22, and the coil 10 is on the front surface of the supporting member 20. The supporting ring 21 has a certain thickness, and thus, the bending degree of the first end segment 11 and the second end segment 12 is reduced, thereby avoiding breakage of the first end segment 11 and the second end segment 12 due to large bending degree. The second groove 232 has an opening on a side close to the circuit board 30. The first end segment 11 and the second end segment 12 extend out of the guide grooves 23 from the openings of the second grooves 232, and further extend to the circuit board 30.

The extending direction of the first end segment 11 and the second end segment 12 is defined by the guide grooves 23, which improves the layout of the coil and improves the stability of the integral structure. The guide grooves 23 further provide physical protection for the first end segment 11 and the second end segment 12 in the guide grooves 23, preventing bending and wear of the first end segment 11 and the second end segment 12 caused by collision or friction between the first end segment 11 and the second end segment 12 and other electronic components.

As shown in FIG. 5, the extending board 22 is provided with a glue groove 24, and the glue groove 24 is filled with fixing glue 25. As shown in FIG. 3 and FIG. 5, the glue groove 24 and the second grooves 232 are arranged on the same side of the extending board 22, and the glue groove 24 is communicated with both two second grooves 232 of the two guide grooves 23. The fixing glue 25 covers surfaces of the first end segment 11 and the second end segment 12, and the first end segment 11 and the second end segment 12 are sticked and fixed in the corresponding guide grooves 23 by the fixing glue 25. As shown in FIG. 5, the glue groove 24 is arranged on a side of the extending board 22 close to the circuit board 30. With such arrangement, the opening of the second groove 232 is sealed by the fixing glue 25, and the first end segment 11 and the second end segment 12 are further fixed.

As shown in FIG. 3 and FIG. 5, the glue groove 24 has a cross-type shape in a plan view. The fixing glue 25 covers on the first end segment 11 and the second end segment 12 along the shape of the glue groove 24, so the fixing glue 25 wraps and fixes the first end segment 11 and the second end segment 12 along the guide groove 23 in all directions.

In some embodiments, the glue groove 24 may also be arranged in other shapes, such as a straight line, a circle, and the like. In some embodiments, the extending board 22 is provided with two glue grooves 24 corresponding to the two second grooves 232, respectively.

In some embodiments, the fixing glue 25 is pressure-sensitive adhesive. Pressure-sensitive adhesive is quickly fixed when a small pressure is applied on the pressure-sensitive adhesive, greatly improving productivity and assembly speed. In addition, the pressure-sensitive adhesive is easily stripped from the extending board 22 when needed, without causing permanent damage to the extending board 22 and the coil 10, and the product can be easily disassembled and repaired.

As shown in FIG. 3 and FIG. 5, each of an outer side of the first end segment 11 and an outer side of the second end segment 12 is provided with a tin layer 28. The tin layers 28 start from the ends, connected to the pads 31, of the first end segment 11 and the second end segment 12, and extend towards the guide grooves 23. The tin layer 28 makes the coil 10 easier to soldered with the pads 31, and improves the soldering efficiency. In addition, the tin layer 28 increases the hardness of the coil 10, makes the first end segment 11 and the second end segment 12 more stable and not easy to bend, and reduces the risk of disconnection caused by quaking at the connection between the end segment and the pad 31. In some embodiments, a length of the tin layer 28 is greater than a maximum distance between the extending board 22 and the circuit board 30. That is, the length of the tin layer 28 is greater than the gap X. Therefore, the parts, between the extending board 22 and the circuit board 30, of the first end segment 11 and the second end segment 12 are all coated with the tin layer 28, ensuring the integral stability. In addition, the parts, in the guide grooves 23, of the first end segment 11 and the second end segment 12 are coated by the tine layer 28, ensuring that the first end segment 11 and the second end segment 12 are not offset when they extend out from the guide grooves 23.

As shown in FIG. 1 to FIG. 5, top end of the supporting ring 21 is connected to a connection member 26, and the connection member 26 has a ring shape. An outer diameter of the connection member 26 is equal to an outer diameter of the supporting ring 21, and an inner diameter of the connection member 26 is less than an inner diameter of the supporting ring 21. The coil assembly in embodiments of the present disclosure may be connected and fixed to other adapted electronic components through the connection member 26 and the supporting ring 21. As shown in FIG. 1 and FIG. 2, each of the connection member 26 and the supporting ring 21 has an adaptive notch for connecting another adapted electronic component.

In some embodiments, the supporting ring 21, the extending board 22, and the connection member 26 are integrally formed. For example, the supporting ring 21, the extending board 22, and the connection member 26 are formed in to one piece. Therefore, the ease of installation of supporting member 20 and the reliability of structure are improved.

In the coil assembly of embodiments of the present disclosure, the extending board is arranged between the circuit board and the supporting ring, the first end segment and the second end segment of the coil are supported and fixed by the extending board, the extending board is further provided with guide grooves, and the pad of the circuit board is located on the extending direction of the guide groove. Therefore, the first end segment and the second end segment are guided by the guide grooves to be aligned with the pads for easy soldering. The parts, between the circuit board and the extending board, of the first end segment and the second end segment are coated with the tin layer, thereby increasing the hardness of the coil and avoiding that the connection between the first and second end segments and the pad is affected by bending and offset of the first and second end segments. In the coil assembly of embodiments of the present disclosure, the alignment between the coil and the pads of the circuit board is improved by guiding and supporting the first and second end segments of the coil, and the efficiency and quality of soldering are improved.

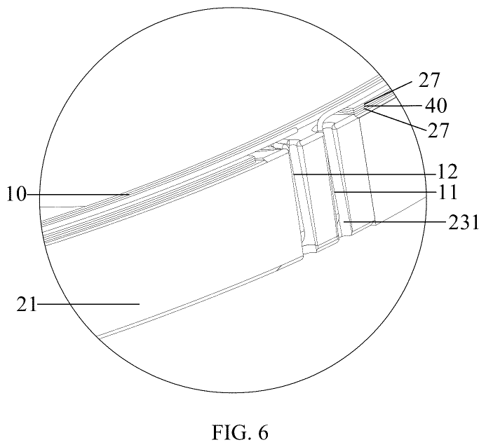

Embodiments of the present disclosure further provide a coil module. The coil module includes a magnetic conductive sheet 40 and the coil assembly described above. The magnetic conductive sheet 40 is disposed on a side of the supporting ring 21. As shown in FIG. 6, the magnetic conductive sheet 40 is connected between the coil 10 and the supporting ring 21. Two glue layers 27 are provided between the coil 10 and the supporting ring 21. The magnetic conductive sheet 40 is sandwiched between the two glue layers 27 and is connected to the coil 10 and the supporting ring 21. The magnetic conductive sheet 40 has a ring shape with a notch, and the notch is provided at a position corresponding to the position of the first groove 231 on the supporting ring 21. The magnetic conductive sheet 40 of this shape avoids mutual obstruction between the magnetic conductive sheet 40 and the coil 10 when the first end segment 11 and the second end segment 12 of the coil 10 extend to the first grooves 231. In addition, the first end segment 11 and the second end segment 12 may be further fixed at the notch, improving the structure stability.

In some embodiments, the magnetic conductive sheet 40 may be arranged on the side of the supporting ring 21 away from the coil 10, and the shape of the magnetic conductive sheet 40 may be a complete ring or designed as a rod, rectangle or other shape as required.

The supporting ring 21 provides a sturdy frame for the magnetic conductive sheet 40 and the coil 10, and improves the structure stability of the overall coil module. In addition, the supporting ring 21 further serves as an effective heat transfer path, and disperses heat from the magnetic conductive sheet 40. Therefore, the overall thermal stability of the coil module is improved, and the durability and reliability of the coil module are improved.

In the coil module of embodiments of the present disclosure, the magnetic conductive sheet is connected between the coil and the supporting ring, and the supporting member improves the integral stability and reliability. With the extending board and the supporting ring, the first end segment and the second end segment of the coil are accurately soldered to the corresponding pads, improving the production efficiency. In addition, the extending board provides supporting for the first end segment and the second end segment of the coil, thereby improving the stability of the connection between the coil and the circuit board and improving the product quality of the coil module.

The above embodiments are exemplary embodiments of the present disclosure and are not intended to limit the present disclosure. The present disclosure may be subject to various modifications and variations to those skilled in the art. Any modifications, equivalent substitutions or improvements that are within the spirit and principle of the disclosure are intended to be covered by the protection scope of the disclosure.

I/We claim:

1. A coil assembly, comprising:
a coil;
a supporting member comprising a supporting ring and an extending board; and
a circuit board,
wherein the circuit board is arranged on an inner side of the supporting ring, a first end of the extending board is connected to the supporting ring, a second end of the extending board extends towards the circuit board, the coil is arranged on the supporting ring, a first end segment and a second end segment of the coil are arranged on the extending board and extend to the circuit board, a first end of the coil is connected to a first pad of the circuit board, and a second end of the coil is connected to a second pad of the circuit board.

2. The coil assembly according to claim 1, wherein the extending board and the circuit board are spaced apart by a gap.

3. The coil assembly according to claim 1, wherein the supporting member comprises two guide grooves, the first end segment and the second end segment extend in the two guide grooves, respectively, and the first pad and the second pad are in an extending direction of the two guide grooves.

4. The coil assembly according to claim 3, wherein each guide groove comprises a first groove and a second groove communicated with the first groove, the first groove is arranged on an outer side of the supporting ring, the second groove is arranged on the extending board, and the second groove has an opening on a side close to the circuit board.

5. The coil assembly according to claim 3, wherein the extending board is provided with a glue groove communicated with both the two guide grooves, the glue groove is filled with fixing glue, the fixing glue covers surfaces of the first end segment and the second end segment, the first end segment (11) is fixed in the one of the two guide grooves by the fixing glue, and the second end segment is fixed in the other one of the two guide grooves by the fixing glue.

6. The coil assembly according to claim 5, wherein the glue groove has a cross-type shape in a plan view.

7. The coil assembly according to claim 1, wherein each of an outer side of the first end segment and an outer side of the second end segment is provided with a tin layer, and a length of the tin layer is greater than a maximum distance between the extending board and the circuit board.

8. The coil assembly according to claim 1, further comprising a connection member, wherein the connection member has a ring shape and is connected to a top end of the supporting ring, an outer diameter of the connection member is equal to an outer diameter of the supporting ring, an inner diameter of the connection member is less than an inner diameter of the supporting ring, and a top surface of the connection member and a top surface of the extending board are located in a same plane.

9. The coil assembly according to claim 1, wherein the supporting ring and the coil are fixed and connected to each other by a glue layer.

10. The coil assembly according to claim 1, wherein the supporting member has a first side and a second side opposite to the first side, the circuit board has a first side and a second side opposite to the first side, the first side of the supporting member and the first side of the circuit board face a same side, the first end segment and the second end segment are arranged on the first side of the supporting member, and the first pad and the second pad are arranged on the second side of the circuit board.

11. The coil assembly according to claim 1, wherein the coil is arranged on the second side of the supporting member.

12. A coil module, comprising: a coil assembly and a magnetic conductive sheet,
wherein the coil assembly comprises: a coil; a supporting member comprising a supporting ring and an extending board; and a circuit board,
wherein the circuit board is arranged on an inner side of the supporting ring, a first end of the extending board is connected to the supporting ring, a second end of the extending board extends towards the circuit board, the coil is arranged on the supporting ring, a first end segment and a second end segment of the coil are arranged on the extending board and extend to the circuit board, a first end of the coil is connected to a first pad of the circuit board, and a second end of the coil is connected to a second pad of the circuit board, and
wherein the magnetic conductive sheet is disposed on a side of the supporting ring.

13. The coil module according to claim 12, wherein the extending board and the circuit board are spaced apart by a gap.

14. The coil module according to claim 12, wherein the supporting member comprises two guide grooves, the first end segment and the second end segment extend in the two guide grooves, respectively, and the first pad and the second pad are in an extending direction of the two guide grooves.

15. The coil module according to claim 14, wherein each guide groove comprises a first groove and a second groove communicated with the first groove, the first groove is arranged on an outer side of the supporting ring, the second groove is arranged on the extending board, and the second groove has an opening on a side close to the circuit board.

16. The coil module according to claim 14, wherein the extending board is provided with a glue groove communicated with both the two guide grooves, the glue groove is filled with fixing glue, the fixing glue covers surfaces of the first end segment and the second end segment, the first end segment (11) is fixed in the one of the two guide grooves by the fixing glue, and the second end segment is fixed in the other one of the two guide grooves by the fixing glue.

17. The coil module according to claim 12, wherein each of an outer side of the first end segment and an outer side of the second end segment is provided with a tin layer, and a length of the tin layer is greater than a maximum distance between the extending board and the circuit board.

18. The coil module according to claim 12, wherein the coil assembly further comprises a connection member, wherein the connection member has a ring shape and is connected to a top end of the supporting ring, an outer diameter of the connection member is equal to an outer diameter of the supporting ring, an inner diameter of the connection member is less than an inner diameter of the supporting ring, and a top surface of the connection member and a top surface of the extending board are located in a same plane.

19. The coil module according to claim 12, wherein the supporting ring and the coil are fixed and connected to each other by a glue layer.

20. The coil module according to claim 12, wherein the supporting member has a first side and a second side opposite to the first side, the circuit board has a first side and a second side opposite to the first side, the first side of the supporting member and the first side of the circuit board face a same side, the first end segment and the second end segment are arranged on the first side of the supporting member, the first pad and the second pad are arranged on the second side of the circuit board, and the coil is arranged on the second side of the supporting member.
